(19) United States
(12) Patent Application Publication
(10) Pub. No.: US 2025/0070516 A1
(43) Pub. Date: Feb. 27, 2025

(54) SIGNAL TRANSFER APPARATUS AND SIGNAL TRANSMISSION SYSTEM

(71) Applicant: SUZHOU METABRAIN INTELLIGENT TECHNOLOGY CO., LTD., Suzhou, Jiangsu (CN)

(72) Inventor: Lingqin KONG, Suzhou, Jiangsu (CN)

(73) Assignee: SUZHOU METABRAIN INTELLIGENT TECHNOLOGY CO., LTD., Suzhou, Jiangsu (CN)

(21) Appl. No.: 18/724,963

(22) PCT Filed: Dec. 27, 2022
(86) PCT No.: PCT/CN2022/142383

§ 371 Date: Jun. 27, 2024

(30) Foreign Application Priority Data
Apr. 29, 2022 (CN) 202210462601.9

(51) Int. Cl. H01R 13/6581; H01R 13/03; H01R 13/05; H05K 1/18

(52) U.S. Cl. CPC H01R 13/6581; H01R 13/03; H01R 13/05; H05K 1/18

(57) ABSTRACT

The present disclosure provides a signal transfer apparatus, comprising: a shielding block, comprising a first flat surface and a second flat surface arranged opposite to each other; at least one group of signal transmission lines, arranged inside the shielding block, wherein two ends of the at least one group of signal transmission lines respectively extend to the first flat surface and the second flat surface, and one end, close to the first flat surface, of the at least one group of signal transmission lines is electrically connected to a circuit board; and a connector, connected to the second flat surface and electrically connected to the other end, close to the second flat surface, of the at least one group of signal transmission lines.

### CROSS-REFERENCE TO RELATED APPLICATION

The present application is a National Stage Application of PCT International Application No.: PCT/CN2022/142383 filed on Dec. 27, 2022, which claims priority to Chinese Patent Application 202210462601.9, filed in the China National Intellectual Property Administration on Apr. 29, 2022, the disclosure of which is incorporated herein by reference in its entirety.

### TECHNICAL FIELD

The present disclosure relates to the technical field of integrated circuits, and in particular, to a signal transfer apparatus and a signal transmission system.

### BACKGROUND

With the rapid development of digital technology, high-speed signal systems such as servers and switches become more and more complex, and the design thereof becomes more and more difficult. The most critical part is a processing manner of a chip on a circuit board, for example, routing and optimization of high-speed signals, and low-voltage high-current power supply design solutions, etc. The fan-out and power supply plane design of high-speed signals in a chip determines the number of layers of the circuit board, determines the cost and complexity of a system solution, and also determines the electrical performance of the system. Pins of the high-speed signals are punched into the inner layer, striplines are transmitted to various positions of a main board in different wiring layers, and signals at each depth of the chip need to occupy one wiring layer. At present, a large-size chip in the industry usually has 6 to 8 depths, that is, 6 to 8 high-speed signal layers are required, and by adding upper and lower reference ground planes, the number of layers of the circuit board usually reaches 20 layers or more. The content above only relates to a high-speed signal part, and for a large-size chip, the power consumption is also relatively high. A chip power supply solution often occupies 6 layers or more of power supply layers, which makes the number of layers of the circuit board higher, and greatly increases the processing difficulty and cost; and the current chip fan-out design method also has the problem of near-end crosstalk; for a high-speed system, a high-level board material with low loss needs to be selected as the material of the circuit board, and the larger the number of layers is, the higher the cost is, which greatly increases the complexity of the system solution and makes the market competitiveness of the products insufficient. In order to solve the described problems, a better chip signal fan-out method needs to be sought, to solve the problems fundamentally.

### SUMMARY

Some embodiments of the present disclosure provide a signal transfer apparatus, includes:
a shielding block, includes a first flat surface and a second flat surface arranged opposite to each other;
at least one group of signal transmission lines, arranged inside the shielding block, wherein two ends of the at least one group of signal transmission lines respectively extend to the first flat surface and the second flat surface, and one end, close to the first flat surface, of the at least one group of signal transmission lines is electrically connected to a circuit board; and
a connector, connected to the second flat surface and electrically connected to the other end, close to the second flat surface, of the at least one group of signal transmission lines.

Further, the end, close to the first flat surface, of the at least one group of signal transmission lines is electrically connected to a bottom surface of the circuit board.

Further, the shielding block is a solid block structure made of a shielding material.

Further, the shielding material is graphite, a boron-containing material or concrete.

Further, there are multiple groups of signal transmission lines, and a distance between every two groups of signal transmission lines gradually increases from the first flat surface to the second flat surface.

Further, the multiple groups of signal transmission lines are arranged in a distributed manner from pins of a chip to the connector.

Further, the shielding block is a trapezoid-shaped platform.

Further, one end of the at least one group of signal transmission lines is connected to pins of the chip by a via on the circuit board, and a distribution position of one end of the at least one group of signal transmission lines on the first flat surface is consistent with a distribution position of the pins of the chip.

Further, one group of signal transmission lines include a first ground line, a second ground line, a first signal line and a second signal line, which are not connected to each other.

Further, the signal transfer apparatus further includes a connecting terminal, wherein one end of the connecting terminal is fixedly connected to the shielding block and is electrically connected to the end, close to the first flat surface, of the at least one group of signal transmission lines, and the other end of the connecting terminal is plugged into the via.

Further, the connecting terminal is made of a hard material.

Further, the connecting terminal is a fish-eye terminal.

Further, the at least one group of signal transmission lines are further configured to connect to high-speed signal pins of the chip.

Further, there are multiple groups of signal transmission lines, there are multiple connectors, and each group of signal transmission lines is connected to a corresponding connector.

Further, a type of the at least one group of signal transmission lines is set on the basis of an attribute of a hardware device for high-speed signal transmission.

Further, the number of the at least one group of signal transmission lines is set on the basis of an attribute of a hardware device for high-speed signal transmission.

Some embodiments of the present disclosure also provide a signal transmission system, includes:
a circuit board;
at least two chips, arranged at intervals on one face of the circuit board;
at least two signal transfer apparatuses as described above, which are correspondingly arranged on the other face of the circuit board, wherein each of the signal transfer apparatuses is electrically connected to one of the chips; and
a connecting cable, two ends of the connecting cable being respectively connected to two signal transfer apparatuses corresponding to two different chips.

Further, the at least two signal transfer apparatuses are arranged on the face of the circuit board facing away from the at least two chips, and the at least two signal transfer apparatuses are fixedly connected to the circuit board by means of fasteners.

Further, the fasteners include screws.

Further, the at least two signal transfer apparatuses are arranged on the face of the circuit board facing away from the at least two chips, chip sockets are connected between the circuit board and the at least two chips, and the at least two signal transfer apparatuses are fixedly connected to the chip sockets by means of fasteners.

### BRIEF DESCRIPTION OF THE DRAWINGS

In order to describe the embodiments in specific embodiments of the present disclosure or in the related art more clearly, hereinafter, drawings requiring to be used for describing the specific embodiments or the related art are introduced briefly. Apparently, the drawings in the following description relate to some embodiments of the present disclosure, and for a person of ordinary skill in the art, other drawings can also be obtained according to these drawings without involving any inventive effort.

FIG. 1 is a schematic structural diagram of an embodiment of a signal transfer apparatus according to at least one embodiments of the present disclosure;

FIG. 2 is a schematic structural diagram of another embodiment of a signal transfer apparatus according to at least one embodiments of the present disclosure;

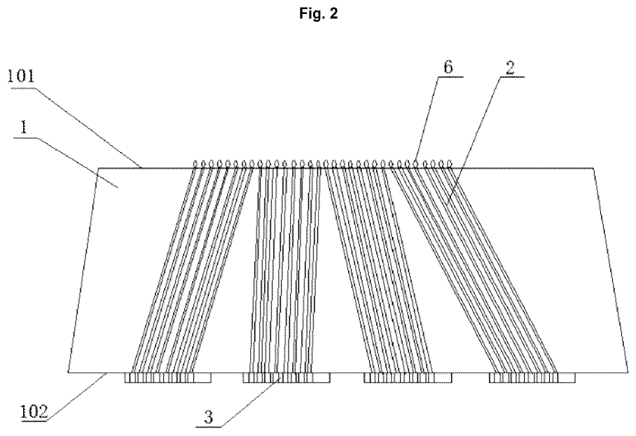

FIG. 3 is a schematic structural diagram of a signal transfer apparatus being plugged into a circuit board according to at least one embodiments of the present disclosure; and

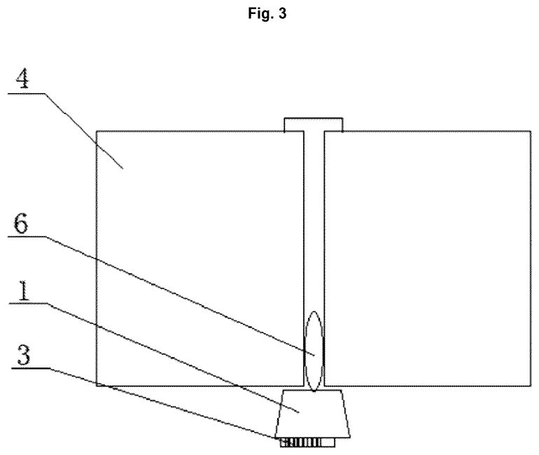

FIG. 4 is a schematic structural diagram of an embodiment of a signal transmission system according to at least one embodiments of the present disclosure.

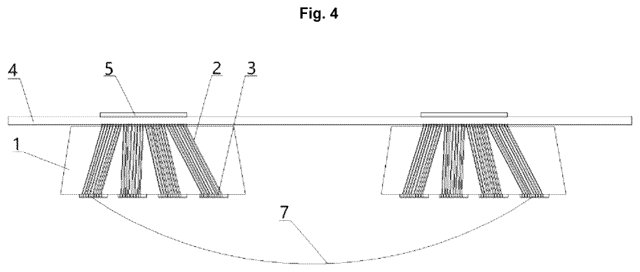

### DESCRIPTION OF REFERENCE SIGNS

1. Shielding block; 101. First flat surface; 102. Second flat surface; 2. Signal transmission line; 201. First ground line; 202. Second ground line; 203. First signal line; 204. Second signal line; 3. Connector; 4. Circuit board; 5. Chip; 6. Connecting terminal; 7. Connecting cable.

### DETAILED DESCRIPTION OF THE EMBODIMENTS

Hereinafter, the embodiments in some embodiments of the present disclosure will be described clearly and thoroughly with reference to the drawings. Obviously, the embodiments as described are only some of the embodiments of the present disclosure, and are not all of the embodiments of the present disclosure. All other embodiments obtained by a person of ordinary skill in the art on the basis of the embodiments of the present disclosure without any inventive effort shall all fall within the scope of protection of the present disclosure.

In the illustration of some embodiments of the present disclosure, it should be understood that orientation or positional relationships indicated by terms such as “center”, “upper”, “lower”, “left”, “right”, “vertical”, “horizontal”, “inner”, “outer” etc. are orientation or positional relationships based on those as shown in the drawings, are only used to facilitate the illustration of the present disclosure and to simplify the illustration, rather than indicating or implying that an apparatus or element referred to must have a specific orientation, and be constructed and operated in the specific orientation, and therefore said terms cannot be understood as limitation to some embodiments of the present disclosure. In addition, the terms “first”, “second” and “third” are used for descriptive purposes only and cannot be construed as indicating or implying relative importance.

In the illustration of some embodiments of the present disclosure, it should be noted that unless specified and limited otherwise, the terms “mount”, “connect to”, and “connecting” should be understood broadly, and for example, may be fixed connection, and may also be detachable connection, or integral connection; may be mechanical connection, and may also be electrical connection; and may be direct connection, and may also be indirect connection by means of an intermediate medium, and may also be interior communication between two elements. For a person of ordinary skill in the art, specific meanings of the described terms in the present disclosure could be understood according to specific situations.

In addition, technical features involved in different embodiments of the present disclosure described below may be combined with each other as long as the technical features do not conflict with each other.

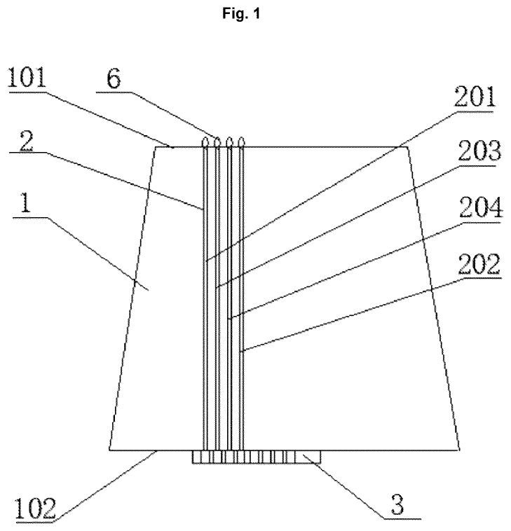

As shown in FIG. 1, some embodiments of the present disclosure provide a signal transfer apparatus, includes: a shielding block 1, at least one group of signal transmission lines 2 and a connector 3; the shielding block 1 includes a first flat surface 101 and a second flat surface 102 arranged opposite to each other; the at least one group of signal transmission lines 2 are arranged inside the shielding block 1, wherein two ends of the at least one group of signal transmission lines 2 respectively extend to the first flat surface 101 and the second flat surface 102, and one end, close to the first flat surface 101, of the at least one group of signal transmission lines 2 is electrically connected to a circuit board 4; and the connector 3 is connected to the second flat surface 102, and is electrically connected to the other end, close to the second flat surface 102, of the at least one group of signal transmission lines 2.

By using this embodiment, by electrically connecting the signal transfer apparatus to the bottom surface of the circuit board 4, all high-speed signals of a chip 5 are led to the signal transfer apparatus through the at least one group of signal transmission lines 2, and then are connected to the chip 5 or other components requiring high-speed signal transmission by the signal transfer apparatus. In this way, high-speed signal pins of the chip 5 do not need to be punched into the inner layer of the circuit board 4, and striplines also do not need to be transmitted to various positions of the circuit board 4 in different wiring layers; high-speed signal wiring layers do not need to be arranged on the circuit board 4, so that near-end crosstalk can be eliminated, the signal integrity of a system is greatly improved, and the high-speed signals can be randomly connected via the connector 3. In addition, the loss of the connector 3 is lower than the loss of wirings of the circuit board 4, so that the solution design of the system is more flexible, and the at least one group of signal transmission lines 2 pass through the shielding block 1, which can reduce the signal mutual interference between the at least one group of signal transmission lines 2.

Specifically, in embodiments, the shielding block 1 is a solid block structure made of a shielding material; and preferably, the shielding material may be graphite, a boron-containing material, concrete, or the like.

It should be noted that, in some embodiments of the present disclosure, not only for the chip 5, the signal transfer apparatus can be used for high-speed signal transmission, and embodiments of the present disclosure are applicable to all other components requiring high-speed signal transmission.

There are multiple groups of signal transmission lines 2, and a distance between every two groups of signal transmission lines 2 gradually increases from the first flat surface 101 to the second flat surface 102.

In this embodiment, the area occupied by the connector 3 on the bottom of the shielding block 1 is large, and thus when there are multiple groups of signal transmission lines 2, a plurality of connectors 3 need to be correspondingly provided for connection. However, pins on the bottom of the chips 5 are dense, and therefore, the signal transmission lines 2 led out from the pins need to be connected to corresponding connectors 3, and the multiple groups of signal transmission lines 2 are arranged in a distributed manner from the pins of the chips 5 to the connectors 3. Hence, the distance between every two groups of signal transmission lines 2 gradually increases from the first flat surface 101 to the second flat surface 102, and a distance between respective groups of signal transmission lines 2 is gradually larger. The purpose is to increase a distance between the pins, such that the pins are smoothly connected to pins of respective connectors 3, and gradually increasing the distance between the respective groups of signal transmission lines 2 can prevent signal crosstalk therebetween.

The shielding block 1 is a trapezoid-shaped platform.

In this embodiment, as the area occupied by the connector 3 on the bottom of the shielding block 1 is large, the shielding block 1 being the trapezoid-shaped platform can reduce the overall occupation area of the signal transfer apparatus, and can also reduce costs.

One end of the at least one group of signal transmission lines 2 is connected to pins of the chip 5 by a via on the circuit board 4, and a distribution position of one end of the at least one group of signal transmission lines 2 on the first flat surface 101 is consistent with a distribution position of the pins of the chip 5.

In this embodiment, the distribution position of one end of the at least one group of signal transmission lines 2 on the first flat surface 101 being consistent with the distribution position of the pins of the chip 5 can reduce wirings of the at least one group of signal transmission lines 2, and the at least one group of signal transmission lines 2 can be directly connected to the pins at the bottom of the chip 5, thereby improving the connection stability and also reducing costs; in addition, corresponding pins can also be directly found for plugging during connection, thereby improving the convenience.

One group of signal transmission lines 2 include a first ground line 201, a second ground line 202, a first signal line 203 and a second signal line 204, which are not connected to each other.

In this embodiment, the one group of signal transmission lines 2 include the first ground line 201, the second ground line 202, the first signal line 203 and the second signal line 204, which are not connected to each other; as the signal transmission lines 2 are located within the shielding block 1, interference between the signal transmission lines 2 can be reduced. It should be noted that the one group of signal transmission lines 2 are not limited to the first ground line 201, the second ground line 202, the first signal line 203 and the second signal line 204. The specific number and type of the signal transmission lines 2 may be set according to actual situations, for example, the type and the number of the signal transmission lines 2 may be set with reference to an attribute of a hardware device requiring high-speed signal transmission.

The present signal transfer apparatus further includes a connecting terminal 6, wherein one end of the connecting terminal 6 is fixedly connected to the shielding block 1 and is electrically connected to the end, close to the first flat surface 101, of the at least one group of signal transmission lines 2, and the other end of the connecting terminal 6 is plugged into the via.

In this embodiment, the connecting terminal 6 is made of a hard material, one end thereof is fixedly connected to the shielding block 1 and is electrically connected to the end, close to the first flat surface 101, of the at least one group of signal transmission lines 2, and the other end of the connecting terminal 6 is plugged into the via, which can facilitate the plugging of the whole signal transfer apparatus into vias of the circuit board 4, and can prevent signal connection lines from breaking due to its own flexible property or instability of high-speed signals caused by rubbing.

The connecting terminal 6 is a fish-eye terminal.

In this embodiment, the connecting terminal 6 is the fish-eye terminal; as the fish-eye terminal itself can be expanded and contracted, the connecting terminal 6 may be pressed and contracted and plugged into the via of the circuit board 4, and then the fish-eye terminal may be tightly clamped into the via of the circuit board 4 by expansion in the via.

Some embodiments of the present disclosure also provide a signal transmission system, includes:
a circuit board 4;
at least two chips 5, arranged at intervals on one face of the circuit board 4;
at least two signal transfer apparatuses as described above, which are correspondingly arranged on the other face of the circuit board 4, wherein each of the signal transfer apparatuses is electrically connected to one of the chips 5; and
a connecting cable 7, two ends of the connecting cable 7 being respectively connected to two signal transfer apparatuses corresponding to two different chips 5.

By the embodiments in some embodiments of the present disclosure, when two chips 5 need to perform high-speed signal transmission, high-speed signal pins of the chips 5 do not need to be punched into the inner layer of the circuit board 4, and striplines also do not need to be transmitted to various positions of the circuit board 4 in different wiring layers; by electrically connecting the signal transfer apparatuses to the bottom surface of the circuit board 4, all high-speed signals of the chips 5 are led to the signal transfer apparatuses through the at least one group of signal transmission lines 2. Then, the signal transfer apparatuses connected to the bottom of the chips 5 are connected to the chips 5 or other components requiring high-speed signal transmission through the connecting cable 7; in this way, high-speed signal wiring layers do not need to be arranged on the circuit board 4, so that near-end crosstalk can be eliminated, the signal integrity of the system is greatly improved, and the high-speed signals can be randomly connected via the connectors 3. In addition, the loss of the connectors 3 is lower than the loss of wirings of the circuit board 4, so that the solution design of the system is more flexible.

The at least two signal transfer apparatuses are arranged on the face of the circuit board 4 facing away from the at least two chips 5, and the at least two signal transfer apparatuses are fixedly connected to the circuit board 4 by means of fasteners.

In this embodiment, the at least two signal transfer apparatuses are fixedly connected to the circuit board 4 by fasteners, wherein the fasteners include accessories that can achieve a fixing function, such as screws, so as to prevent the at least two signal transfer apparatuses from falling off, thereby improving the stability of the at least two signal transfer apparatuses.

The at least two signal transfer apparatuses are arranged on the face of the circuit board 4 facing away from the at least two chips 5, chip sockets are connected between the circuit board 4 and the at least two chips 5, and the at least two signal transfer apparatuses are fixedly connected to the chip sockets by means of fasteners.

In this embodiment, when the chip sockets are connected between the circuit board 4 and the at least two chips 5, the signal transfer apparatuses and the chip sockets may be together fixedly mounted on the circuit board 4 by means of fasteners, without adding new fixing fasteners, thereby reducing costs.

Some embodiments of the present disclosure have the following advantages:
1. By using the embodiments in some embodiments of the present disclosure, by electrically connecting the signal transfer apparatus to the bottom surface of a circuit board, all high-speed signals of a chip are led to the signal transfer apparatus through signal transmission lines, and then are connected to the chip or other components requiring high-speed signal transmission by the signal transfer apparatus. In this way, high-speed signal pins of the chip do not need to be punched into the inner layer of the circuit board, and striplines also do not need to be transmitted to various positions of the circuit board in different wiring layers; high-speed signal wiring layers do not need to be arranged on the circuit board, so that near-end crosstalk can be eliminated, the signal integrity of a system is greatly improved, and the high-speed signals can be randomly connected via a connector. In addition, the loss of the connector is lower than the loss of wirings of the circuit board, so that the solution design of the system is more flexible, and the signal transmission lines pass through a shielding block, which can reduce the signal mutual interference between the signal transmission lines.
2. As the area occupied by the connector on the bottom of the shielding block is large, the shielding block being a trapezoid-shaped platform can reduce the overall occupation area of the signal transfer apparatus, and can also reduce costs. The trapezoid-shaped block structure can gradually increase a distance between respective groups of signal transmission lines. The purpose is to increase a distance between the pins, such that the pins are smoothly connected to pins of respective connectors, and gradually increasing the distance between the respective groups of signal transmission lines can prevent signal crosstalk therebetween.
3. A connecting terminal can transmit high-speed signals transmitted by the chips through the vias of the circuit board to the signal transmission lines, and arranging the connecting terminal can facilitate the plugging and unplugging of the whole signal transfer apparatus and facilitate the installation.
4. The connecting terminal is made of a hard material, one end thereof is fixedly connected to the shielding block and is electrically connected to the end, close to a first flat surface, of the signal transmission lines, and the other end of the connecting terminal is plugged into the via, which can facilitate the plugging of the whole signal transfer apparatus into vias of the circuit board, and can prevent signal connection lines from breaking due to its own flexible property or instability of high-speed signals caused by rubbing.
5. The connecting terminal is a fish-eye terminal; as the fish-eye terminal itself can be expanded and contracted, the connecting terminal may be pressed and contracted and plugged into the via of the circuit board, and then the fish-eye terminal may be tightly clamped into the via of the circuit board by expansion in the via.

Apparently, the described embodiments are merely examples made for clear illustration, and are not intended to limit the embodiments. For a person of ordinary skill in the art, other variations or modifications of different forms may be made on the basis of the described illustration. Herein, it is neither necessary nor possible to list all embodiments in an exhaustive manner. Moreover, obvious variations or modifications derived therefrom are still within the scope of protection of the present disclosure and creation.

1. A signal transfer apparatus, comprising:
a shielding block, comprising a first flat surface and a second flat surface arranged opposite to each other;
at least one group of signal transmission lines, arranged inside the shielding block, wherein two ends of the at least one group of signal transmission lines respectively extend to the first flat surface and the second flat surface, and one end, close to the first flat surface, of the at least one group of signal transmission lines is electrically connected to a circuit board; and
a connector, connected to the second flat surface, and electrically connected to the other end, close to the second flat surface, of the at least one group of signal transmission lines.

2. The signal transfer apparatus as claimed in claim 1, wherein the end, close to the first flat surface, of the at least one group of signal transmission lines is electrically connected to a bottom surface of the circuit board.

3. The signal transfer apparatus as claimed in claim 1, wherein the shielding block is a solid block structure made of a shielding material.

4. The signal transfer apparatus as claimed in claim 3, wherein the shielding material is graphite, a boron-containing material or concrete.

5. The signal transfer apparatus as claimed in claim 1, wherein there are multiple groups of signal transmission lines, and a distance between every two groups of signal transmission lines gradually increases from the first flat surface to the second flat surface.

6. The signal transfer apparatus as claimed in claim 5, wherein the multiple groups of signal transmission lines are arranged in a distributed manner from pins of a chip to the connector.

7. The signal transfer apparatus as claimed in claim 5, wherein the shielding block is a trapezoid-shaped platform.

8. The signal transfer apparatus as claimed in claim 1, wherein one end of the at least one group of signal transmission lines is connected to pins of a chip by a via on the circuit board, and a distribution position of one end of the at least one group of signal transmission lines on the first flat surface is consistent with a distribution position of the pins of the chip.

9. The signal transfer apparatus as claimed in claim 8, wherein one group of signal transmission lines comprise a first ground line, a second ground line, a first signal line and a second signal line, which are not connected to each other.

10. The signal transfer apparatus as claimed in claim 8, wherein the signal transfer apparatus further comprises a connecting terminal, wherein one end of the connecting terminal is fixedly connected to the shielding block and is electrically connected to the end, close to the first flat surface, of the at least one group of signal transmission lines, and the other end of the connecting terminal is plugged into the via.

11. The signal transfer apparatus as claimed in claim 10, wherein the connecting terminal is made of a hard material.

12. The signal transfer apparatus as claimed in claim 10, wherein the connecting terminal is a fish-eye terminal.

13. The signal transfer apparatus as claimed in claim 1, wherein the at least one group of signal transmission lines are further configured to connect to high-speed signal pins of a chip.

14. The signal transfer apparatus as claimed in claim 1, wherein there are multiple groups of signal transmission lines, there are multiple connectors, and each group of signal transmission lines is connected to a corresponding connector.

15. The signal transfer apparatus as claimed in claim 1, wherein a type of the at least one group of signal transmission lines is set on the basis of an attribute of a hardware device for high-speed signal transmission.

16. The signal transfer apparatus as claimed in claim 1, wherein the number of the at least one group of signal transmission lines is set on the basis of an attribute of a hardware device for high-speed signal transmission.

17. A signal transmission system, comprising:
a circuit board;
at least two chips, arranged at intervals on one face of the circuit board;
at least two signal transfer apparatuses as claimed in claim 1, which are correspondingly arranged on the other face of the circuit board, wherein each of the signal transfer apparatuses is electrically connected to one of the chips; and
a connecting cable, two ends of the connecting cable being respectively connected to two signal transfer apparatuses corresponding to two different chips.

18. The signal transmission system as claimed in claim 17, wherein the at least two signal transfer apparatuses are arranged on the face of the circuit board facing away from the at least two chips, and the at least two signal transfer apparatuses are fixedly connected to the circuit board by means of fasteners.

19. The signal transmission system as claimed in claim 18, wherein the fasteners comprise screws.

20. The signal transmission system as claimed in claim 17, wherein the at least two signal transfer apparatuses are arranged on the face of the circuit board facing away from the at least two chips, chip sockets are connected between the circuit board and the at least two chips, and the at least two signal transfer apparatuses are fixedly connected to the chip sockets by means of fasteners.
